(19) United States
(12) Patent Application Publication
(10) Pub. No.: US 2024/0339384 A1
(43) Pub. Date: Oct. 10, 2024

(54) FLIP CHIP SEMICONDUCTOR DEVICE PACKAGE

(71) Applicant: Texas Instruments Incorporated, Dallas, TX (US)

(72) Inventors: Ymarson Algamas Bangaga, Baguio City (PH); Patricio V. Ancheta, JR., Baguio City (PH); Rachel F. Dulatre, Baguio City (PH)

(21) Appl. No.: 18/193,506

(22) Filed: Mar. 30, 2023

(51) Int. Cl. H01L 23/495; H01L 21/56; H01L 23/31

(52) U.S. Cl. CPC H01L 23/49548; H01L 21/565; H01L 23/3128; H01L 23/4952; H01L 23/49575

(57) ABSTRACT

An example apparatus includes: a leadframe having upset leads, the leads further including: an external portion with a board side surface in a first plane; an internal portion extending from the external portion and having an upper surface opposite the board side surface; an angled portion extending from the internal portion and forming an angle with the upper surface; and an elevated portion extending from the angled portion and having a device side surface lying in a second plane parallel to the first plane. A mold lock feature includes an indenture into the upper surface or the angle being either a normal angle or an acute angle formed between the upper surface and the angled portion. A semiconductor die is flip chip mounted to the elevated portion of the leads. Mold compound covers the semiconductor die and is in contact with the mold lock feature of the leads.

### TECHNICAL FIELD

This relates generally to packaging electronic devices, and more particularly to assembling flip chip packaged semiconductor devices.

### BACKGROUND

Processes for producing packaged semiconductor devices include mounting semiconductor devices to a package substrate, and covering the electronic devices with a mold compound to form semiconductor device packages. When semiconductor devices are mounted on package substrates in flip chip packages, a semiconductor die may have conductive post connects that extend from bond pads on a device side surface of the semiconductor die to a distal end having a solder ball or solder bump. In a flip chip package, the semiconductor die can be mounted with the device side surface facing a package substrate. When the semiconductor die is flip chip mounted to the package substrate, the solder bumps at the distal end of the post connects are subjected to a thermal reflow process so that the solder melts and flows to form solder joints to the package substrate. The solder joints mechanically attach and electrically couple bond pads on the semiconductor device to the package substrate. The solder joints attach the conductive post connects to conductive areas on the package substrate. In an example the package substrate is conductive lead frame with leads that have the conductive post connects soldered to a portion of the leads, with the leads having an internal portion covered by the mold compound extending to an external portion that form terminals for the semiconductor device package.

Certain semiconductor device packages using flip chip mounting for the semiconductor die can be referred to as “flip chip on lead” or “FCOL” packages. Some of these semiconductor device packages are used for devices having relatively low pin counts such as discrete transistors arranged as gate controlled switches, logic functions such as NAND, NOR, XOR devices, sensors, and power transistors such as power field effect transistors (FETs). In production of these devices, packages referred to as “small outline transistor” (SOT) packages can be used. Example SOT packages have 5, 6, 8 or 16 terminals or pins. In these packages, delamination and package cracking defects are observed. Delamination occurs during manufacture or during in field use of the packaged devices when the mold compound cracks or pulls apart from the package substrate. A flip chip semiconductor device package and method of assembly that reduces or prevents these delamination defects is needed.

### SUMMARY

In an example, a method includes: forming an upset leadframe having leads configured for flip chip mounting a semiconductor die, the leads. The leads include an external portion with a board side surface in a first plane; an internal portion extending from an interior end of the external portion, the internal portion having an upper surface opposite the board side surface, the internal portion lying in the first plane; an angled portion extending from the internal portion opposite the external portion, the angled portion forming an angle with the upper surface and extending away from the internal portion; an elevated portion extending from the angled portion, the elevated portion having a device side surface facing opposite the board side surface and lying in a second plane that is parallel to the first plane; and a mold lock feature having either an indenture into the upper surface of the internal portion or the angle of the angled portion being either a normal angle or an acute angle formed between the upper surface of the internal portion and the angled portion. The method continues by flip chip mounting a semiconductor die to the elevated portion of the leads by forming a solder joint between a solder bump on a post connect extending from the semiconductor die and the elevated portion of the leads. The semiconductor die, the elevated portion, the angled portion, and the internal portion of the leads are covered with mold compound, the mold compound in contact with the mold lock features, the external portions of the leads exposed from the mold compound, and the board side surface of the external portions forming terminals of a semiconductor device package.

In an additional described example, an apparatus includes: a leadframe having upset leads configured for flip chip mounting a semiconductor die, the leads further including: an external portion with a board side surface in a first plane; an internal portion extending from an interior end of the external portion, the internal portion having an upper surface opposite the board side surface; an angled portion extending from the internal portion opposite the external portion, the angled portion forming an angle with the upper surface of the internal portion and extending away from the internal portion; an elevated portion extending from the angled portion, the elevated portion having a device side surface opposite the board side surface and lying in a second plane parallel to the first plane; and a mold lock feature comprising an indenture into the upper surface of the internal portion or the angle of the angled portion being either a normal angle or an acute angle formed between the upper surface of the internal portion and the angled portion. A semiconductor die is flip chip mounted to the elevated portion of the leads by solder joints between a solder bump on a post connect extending from the semiconductor die and the elevated portion of the leads. Mold compound covers the semiconductor die, the post connects, the elevated portion, the angled portion, and the internal portion of the leads of the leadframe, the mold compound in contact with the mold lock feature of the leads, the external portions of the leads exposed from the mold compound, and the board side surface of the external portions of the leads forming terminals.

In an additional method, a method for forming an upset leadframe includes: forming leads configured for receiving a flip chip mounted semiconductor die, each of the leads including: an external portion with a board side surface in a first plane; an internal portion extending from an interior end of the external portion, the internal portion having an upper surface opposite the board side surface, the internal portion lying in the first plane; an angled portion extending from the internal portion opposite the external portion, the angled portion forming an angle with the upper surface and extending away from the internal portion; an elevated portion extending from the angled portion, the elevated portion having a device side surface facing opposite the board side surface and lying in a second plane that is parallel to the first plane; and a mold lock feature comprising either an indenture into the upper surface of the internal portion or the angle of the angled portion being either a normal angle or an acute angle formed between the upper surface of the internal portion and the angled portion.

### BRIEF DESCRIPTION OF THE DRAWINGS

FIGS. 1A-1B illustrate in two projection views a semiconductor wafer including semiconductor dies and an individual semiconductor die from the wafer, respectively, the semiconductor dies are arranged for flip chip mounting.

FIGS. 2A-2B illustrate a semiconductor device package in a top projection view and a bottom projection view, respectively.

FIGS. 3A-3E illustrate in a series of cross-sectional views selected steps in manufacturing a flip chip semiconductor device package using a leadframe, while FIGS. 3F and 3G illustrate a stress plane on an end view and in a cross sectional view of a flip chip semiconductor device package, respectively.

FIGS. 4A-4GG illustrate, in a series of projection views (FIGS. 4A-4G) and a series of corresponding cross-sectional views (FIGS. 4AA-4GG, in correspondence to FIGS. 4A-4G), example arrangements including mold lock features for an upset flip chip on lead leadframe.

FIG. 5 illustrates, in a cross sectional view, an example arrangement for a flip chip semiconductor device package that includes selected mold lock features.

FIG. 6 illustrates, in a flow diagram, a method for forming an arrangement.

### DETAILED DESCRIPTION

Corresponding numerals and symbols in the different figures generally refer to corresponding parts, unless otherwise indicated. The figures are not necessarily drawn to scale.

Elements are described herein as “coupled.” The term “coupled” includes elements that are directly connected and elements that are indirectly connected, and elements that are electrically connected even with intervening elements or wires are coupled.

The term “semiconductor die” is used herein. As used herein, a semiconductor die can be a discrete semiconductor device such as a bipolar transistor, a few discrete devices such as one or a pair of power FET switches fabricated together on a single semiconductor die, or a semiconductor die can be an integrated circuit with multiple semiconductor devices such as multiple capacitors used in an A/D converter. The semiconductor die can include passive devices such as resistors, inductors, filters, capacitors, diodes or active devices such as transistors. The semiconductor die can be an integrated circuit with hundreds or thousands of transistors coupled to form a functional circuit, for example for a microprocessor or memory device. The semiconductor die can be a passive device such as a sensor, example sensors include photocells, transducers, and charge coupled devices (CCDs), or can be a micro electro-mechanical system (MEMS) device, such as a digital micromirror device (DMD). The semiconductor die includes a semiconductor substrate that has a device side surface and an opposite backside surface. Semiconductor processes form the devices on the device side surface of the semiconductor die.

The term “packaged semiconductor device” is used herein. A packaged semiconductor device has at least one semiconductor die electronically coupled to terminals that has a package body that protects and covers the semiconductor die. In some arrangements, multiple semiconductor dies can be packaged together. For example, a power metal oxide semiconductor (MOS) field effect transistor (FET) semiconductor die and a logic semiconductor die (such as a gate driver die or controller device die) can be packaged together to from a single packaged electronic device. Additional components such as passives can be included in the packaged electronic device. The semiconductor die can be mounted to a package substrate that provides conductive leads, a portion of the conductive leads form the terminals for the semiconductor device package. The semiconductor die can be flip chip mounted with the device side surface facing a package substrate surface, and the semiconductor die is mounted to the leads of the package substrate by conductive post connects attached to the package substrate by solder such as solder balls or bumps. The semiconductor device package can have a package body formed by a thermoset epoxy resin in a molding process, or by the use of epoxy, plastics, or resins that are liquid at room temperature and are subsequently cured. The package body may provide a hermetic package for the packaged electronic device. The package body may be formed in a mold using an encapsulation process, however, a portion of the leads of the package substrate are not covered during encapsulation, these exposed lead portions provide the terminals for the semiconductor device package.

The term “package substrate” is used herein. A package substrate is a substrate arranged to receive a semiconductor die and to support the semiconductor die in a completed semiconductor device package. Package substrates include conductive lead frames, which can be formed from copper, aluminum, stainless steel and alloys such as Alloy 42 and copper alloys. For flip chip packages, a portion of the leads receive solder joints between the leads and the conductive post connects for the semiconductor die. The solder joints form the physical die attach and the electrical connection between the semiconductor die and the package substrate. When lead frames are used as package substrates, the lead frames can be provided in strips or arrays. Dies can be placed on the strips or arrays, the dies flip chip mounted to the lead frames and the lead frames and dies then covered with mold compound in a molding process.

Alternative package substrates include pre-molded lead frames (PMLF) and molded interconnect substrates (MIS) for receiving semiconductor dies. Multiple layer substrates, which include multiple levels of conductors in dielectric material, can be used. These package substrates can include dielectrics such as Ajinomoto build up film (ABF), liquid crystal polymer (LCP), or mold compound, and can include one or more layers of patterned conductive portions in the dielectrics. Repeated plating and patterning can form multiple layers of conductors spaced by dielectrics, and layers having conductive vias connecting the conductor layers through the dielectrics.

The package substrates can include lead frames, and can include plated, stamped and partially etched lead frames. In a partially etched lead frame, two levels of metal with differing patterns can be formed by etching a pattern from one side of a metal substrate configured for lead frames, and then etching from the other side, to form full thickness and partial thickness portions, and in some areas, all of the metal can be etched through to form openings through the partial etch lead frames. The package substrate can also be tape-based and film-based, and these can form substrates carrying conductors. Ceramic substrates, laminate substrates with multiple layers of conductors and insulator layers; and printed circuit board substrates of ceramic, fiberglass or resin, or glass reinforced epoxy substrates such as flame retardant 4 (FR4) can be used as the package substrates.

The term “post connect” is used herein. As used herein, a post connect is a structure made of a conductive material, for example copper or copper alloys, gold or gold alloys, or combinations of conductive metal that provides a connection between a semiconductor die and a package substrate. A proximal end of a post connect is mounted to a bond pad on the device side surface of a semiconductor die, while a distal end of the post connect is extended away from the bond pad of the semiconductor die. When the package substrate is oriented in a horizontal direction and the semiconductor die is positioned over and facing a die mount surface of a package substrate in a flip chip orientation, the post connect makes a vertical connection between a conductive portion of the package substrate and a bond pad of the semiconductor die. Some references describe a type of post connect as a “controlled collapse chip connection” or as “C4” bumps. The conductive post connect includes a post of conductor material and has a distal end facing away from the surface of the bond pad on the semiconductor die, where a proximal end of the post connect is mounted to the bond pad by solder joints.

A package substrate, such as a lead frame, has conductive portions on a die side surface. Leads of a metal lead frame can be conductive all along the surfaces, while for other substrate types, conductive lands in dielectric substrate material are arranged and aligned to electrically and mechanically connect to the conductive post connects. The post connects can be various shapes and can extend along the same direction as a conductive lead in the package substrate, so that the post connect appears as a rail or has a rectangular cross section. When the post connect is copper and is pillar shaped and has solder bumped at the end, it may be referred to as a “copper pillar bump.” A copper pillar bump or copper bump is therefore an example of a post connect. In addition to the pillar shape, the post connect can also be a column, rectangle or rail shape, and can have an oval, round, square or rectangular cross section. In examples, multiple post connects can be arranged in parallel to one another with additional post connects coupled to a common trace on a package substrate, to provide a low resistance path between the semiconductor die and the package substrate. A thermal reflow process is used to melt solder between the post connect and the package substrate to make a solder joint. The solder joint provides both a mechanical attachment and an electrical connection between the semiconductor die and the package substrate.

In a discrete device or power transistor package, only a few post connects may be used. The conductive post connects can be, in some examples, a uniform size and have uniform or minimum pitch between them. In other examples, the size of the post connects can be made larger for power terminals or for high current signals, and smaller for control signals or logic signals that require less current, and may have varying spacing distances. Multiple post connects can be coupled in parallel to reduce resistance for certain signals, such as a high current signal, power or ground signal. Post connects can vary in size and shape, but in examples range from 10-70 microns in diameter, and may range from 20-50 microns in height extending away from the bond pad surface on the semiconductor die. As device sizes continue to fall and the density of connections rises, these sizes may decrease. Spacing between post connects may also decrease.

In packaging semiconductor devices, mold compound may be used to partially cover a package substrate, to cover the semiconductor die, and to cover the connections from the semiconductor die to the package substrate. This “encapsulation” process is often a transfer molding process, where thermoset mold compound such as epoxy resin can be used. A room temperature solid or powder mold compound can be heated to a liquid state and then molding can be performed. Unit molds shaped to surround an individual device may be used, or block molding may be used, to form the packages simultaneously for several devices using molten mold compound. The devices can be provided in an array of several, hundreds or even thousands of devices in rows and columns that are molded together. After the molding, the individual packaged devices are cut from each other in a sawing operation by cutting through the mold compound and package substrate in saw streets formed between the devices. Portions of the package substrate leads are exposed from the mold compound of the package to form terminals for the semiconductor device package.

In flip chip semiconductor die mount processes, solder balls, solder columns, or solder bumps are used to form solder joints between the conductive post connects and a conductive lead or land on a package substrate. The post connects are formed extending from bond pads of the semiconductor die. The semiconductor die is then oriented with the distal ends of the post connects facing a die mounting surface of a circuit board or package substrate. A solder reflow process is used to attach the post connects to conductive die pads or leads on the package substrate, the solder joints forming a physical attachment and an electrical connection between the package substrate and the semiconductor die.

The term “scribe lane” is used herein. A scribe lane is a portion of semiconductor wafer between semiconductor dies. Sometimes in related literature the term “scribe street” is used. Once semiconductor processing is finished and the semiconductor devices are complete, the semiconductor devices are separated into individual semiconductor dies by severing the semiconductor wafer along the scribe lanes. The separated dies can then be removed and handled individually for further processing including packaging. This process of removing dies from a wafer is referred to as “singulation” or sometimes referred to as “dicing.” Scribe lanes are arranged on four sides of semiconductor dies and when the dies are singulated from one another, rectangular semiconductor dies are formed.

The term “saw street” is used herein. A saw street is an area between molded electronic devices used to allow a saw, such as a mechanical blade, laser or other cutting tool to pass between the molded electronic devices to separate the devices from one another. This process is another form of singulation. When the molded electronic devices are provided in a strip with one device adjacent another device along the strip, the saw streets are parallel and normal to the length of the strip. When the molded electronic devices are provided in an array of devices in rows and columns, the saw streets include two groups of parallel saw streets, the two groups are angled with respect to each other and so the saw will traverse the molded electronic devices in two different directions to cut apart the packaged electronic devices from one another in the array.

The term “quad flat no-lead” or “QFN” is used herein for a type of electronic device package. A QFN package has conductive leads that are coextensive with the sides of a molded package body and the leads are on four sides. Alternative flat no-lead packages may have leads on two sides or only on one side. These can be referred to as “small outline no-lead” or “SON” packages. No lead packaged electronic devices can be surface mounted to a board. Leaded packages can be used with the arrangements where the leads extend away from the package body and are shaped to form a portion for soldering to a board. A dual in line package, or DIP, can be used with the arrangements. A “small outline transistor” package or “SOT” package can be used with the arrangements. SOT packages can have terminals that extend a small distance from the package body, and in an example arrangement, the terminals are on a board side surface of the SOT package and are configured to be surface mounted to a system board or module using surface mount technology (SMT) to form solder connections. SOT packages can use less system board area than some other package types, such as “dual in line packages” or “DIPs”.

In the arrangements, a semiconductor die has post connects mounted with a proximate end on bond pads on a device side surface of the semiconductor die, and has solder balls or bumps formed on a distal end of the post connects. The semiconductor die is flip chip mounted to a lead frame. In an example arrangement the leadframe has leads with an upset lead configuration. The upset leads have a board side portion that are aligned to one another and lie in a first plane, and the leads extend from an external portion that form the terminals for the semiconductor device package to an internal portion that is covered by the mold compound. An angled portion of the upset leads extends from an interior end of the internal portion at an angle and extend to an elevated portion. The elevated portion extends from the angled portion in a second plane that is spaced from the board side portion of the leads, the second plane is parallel to the first plane. The elevated portion of the upset leads has a device side surface facing away from the board side portion of the leads, the device side surface of the elevated portion of the leads is arranged to receive a post connect of a semiconductor die.

Portions of the upset leads and the semiconductor die are covered in mold compound. In an example arrangement, the internal portion of the upset leads has a mold lock feature that increases adhesion of the mold compound to the leads, and reduces or prevents the delamination defects in semiconductor device packages formed without use of the arrangements. The mold lock features of the arrangements include features that are indentures into an upper surface of the internal portion, alternatively the angle used to form the upset leads is a reverse or normal angle with respect to the internal portion, use of these angles for the angled portions enable an increase in the surface area of the internal portion of the upset lead. The indentures into the upper surface of the internal portion can be formed by stamping or etching operations on the internal portion, and include dips, grooves, and canals that extend the dip or groove shapes across the internal portion, to increase the surface area at the mold compound interface to the internal portion. Alternatively the mold lock feature can be a normal or reversed angle at the intersection of the internal portion with the angled portion, these angles enable an increase in the surface area of the internal portion. The mold lock features of an indenture into the internal portion and a normal or reversed angle can be combined to provide further arrangements.

In an example method arrangement, a leadframe has upset leads. The upset leads have an external portion that form terminals for a semiconductor device package, and an internal portion that will be covered by mold compound, the internal portion extending from the external portion. The external portion and the internal portion of the upset leads lie in a first plane on a board side surface. An angled portion extends from an inside end of the internal portion at a first angle with respect to the internal portion to an elevated portion. The elevated portions of the upset leads lie in a second plane that is parallel to the first plane. The elevated portions of the upset leads have die mount locations on a device side surface facing away from the board side surface, the die mount locations are arranged to receive post connects. In the arrangements, the internal portion of the upset leads includes a mold lock feature that is formed in a upper surface of the upset lead. The mold lock feature can be an indenture formed in the internal portion of the upset lead by etching or stamping, or alternatively the mold lock feature can be a normal or reversed angle at the intersection of the internal portion with the angled portion, these angles enable an increase in the surface area of the internal portion. The mold lock features can be combined to provide additional arrangements. A semiconductor die is flip chip mounted to the elevated portion of the upset leads of the lead frame using a solder reflow process. Molding is used to form a package body from mold compound that covers the semiconductor die, the post connects, the elevated portion of the upset leads, and the internal portion of the upset leads, while the external portion of the leads is exposed from the mold compound to form the terminals for the packaged semiconductor device.

Use of the arrangements reduces or prevents mold compound delamination defects between the leads and the mold compound.

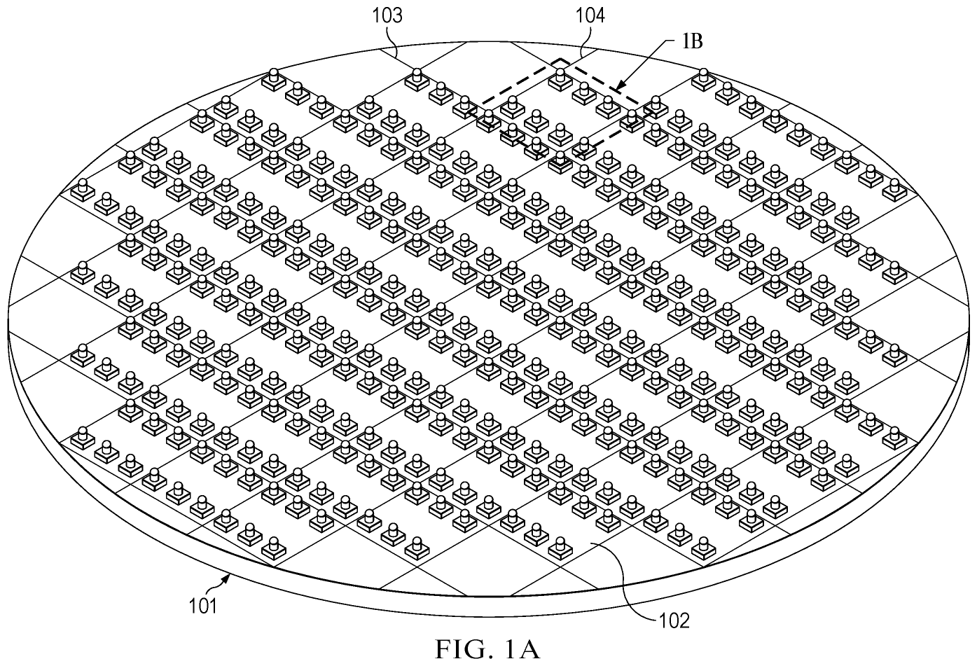

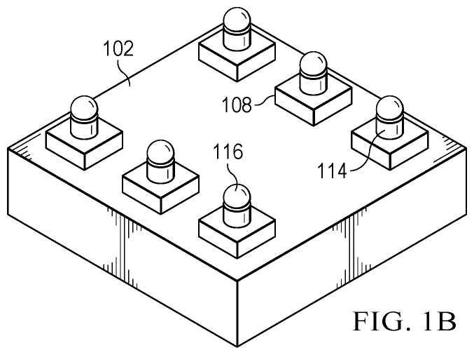

FIG. 1A illustrates a semiconductor wafer 101 shown with an array of semiconductor dies 102 in rows and columns formed on a device side surface of the semiconductor wafer 101. The semiconductor dies 102 are formed using processes in a semiconductor manufacturing facility, including ion implant doping, anneal, oxidation, dielectric and metal deposition, photolithography, pattern, etch, chemical mechanical polishing (CMP), electroplating, and other processes for making semiconductor devices. Vertical and horizontal (as the semiconductor wafer is oriented in FIG. 1A) scribe lanes 103 and 104, which are perpendicular to one another and which run in parallel groups across the wafer, separate the rows and columns of the completed semiconductor dies 102, and provide areas for dicing the wafer to separate the semiconductor dies 102 from one another.

FIG. 1B illustrates a single semiconductor die 102, with bond pads 108, which are conductive pads that are electrically coupled to devices formed in the semiconductor die 102. Conductive post connects 114 are shown extending away from a proximate end mounted on the bond pads 108 on the active surface of semiconductor die 102, and solder bumps 116 are formed on the distal ends of the conductive post connects 114. The conductive post connects can be formed by electroless or electroplating. In an example, the conductive post connects are copper pillar bumps. Copper pillar bumps can be formed by sputtering a seed layer over the surface of the semiconductor wafer 101, forming a photoresist layer over the seed layer, using photolithography to expose the bond pads 108 in openings in the layer of photoresist, plating the copper conducive post connects 114 on the bond pads, and plating a lead based solder or a lead-free solder such as an tin, silver (SnAg) or tin, silver, copper (SnAgCu) (or “SAC”) solder to form solder bumps 116 on the copper conductive post connects 114. Other conductive materials can be used for the conductive post connects in an electroplating or electroless plating operation, including silver, nickel, palladium, or tin, for example. Not shown for clarity of illustration are under bump metallization (UBM) which can be formed over the bond pads to improve plating and adhesion between the conductive post connects and the bond pads 108. After the plating operations, the photoresist is then stripped, and the excess seed layer is etched from the surface of the wafer. The semiconductor dies are then separated by dicing, or are singulated, using the scribe lanes 103, 104 (see FIG. 1A).

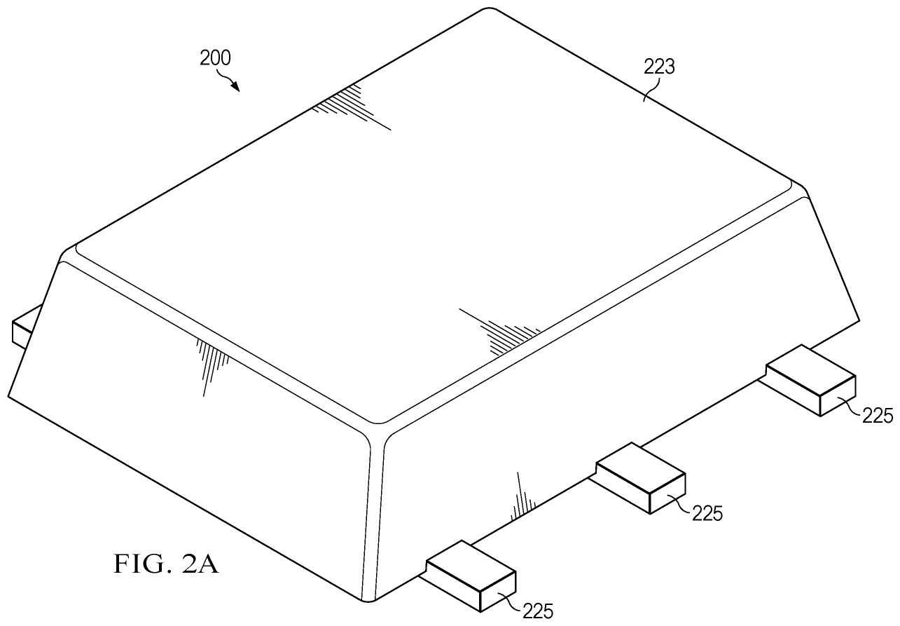

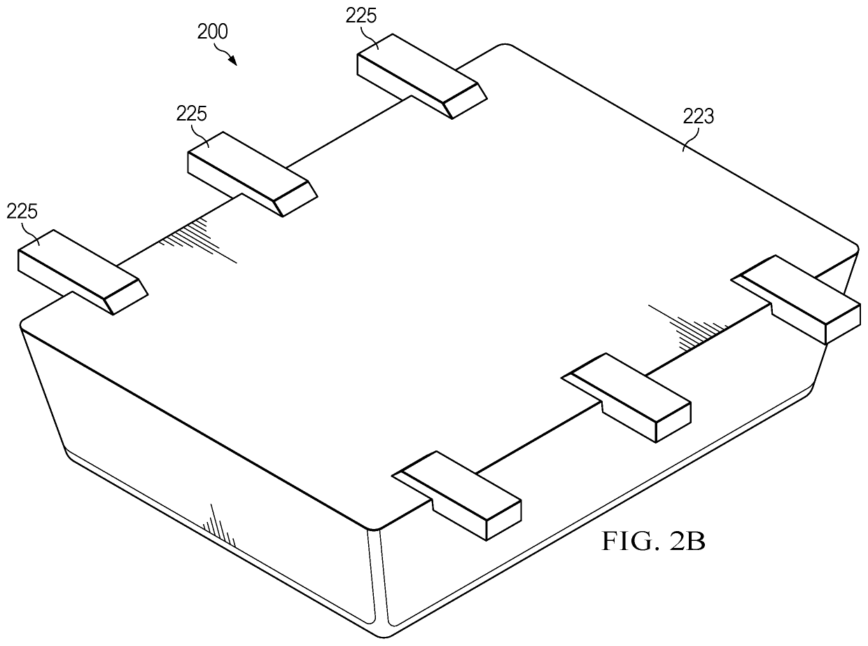

FIG. 2A illustrates in a top side view a semiconductor device package 200 in a projection view. The example semiconductor device package is an SOT package with six terminals 225. The SOT package has a mold compound 223 that covers a semiconductor device die (not visible) and leads with external portions forming terminals 225 for the semiconductor device package 200.

FIG. 2B illustrates the semiconductor device package 200 in a bottom side view. Terminals 225 can be seen with a board side surface that extends from beneath the mold compound 223 a short distance away from the mold compound, providing surface mount capability for the semiconductor device package 200.

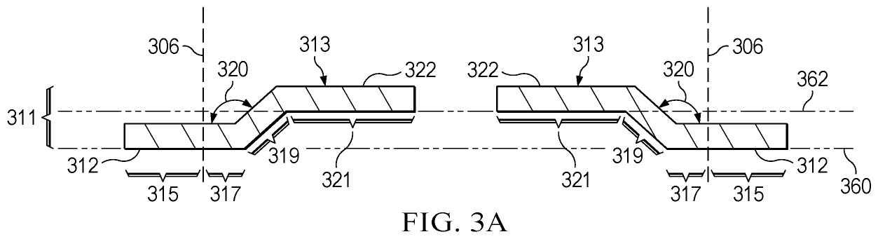

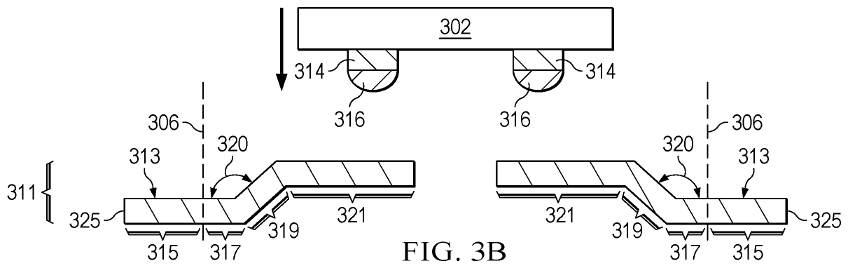

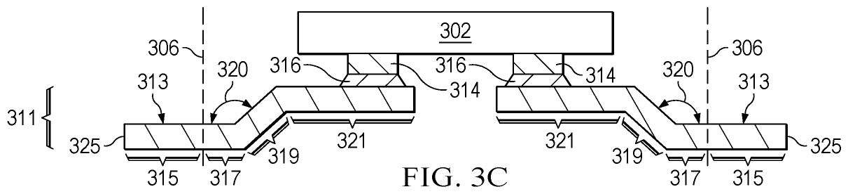

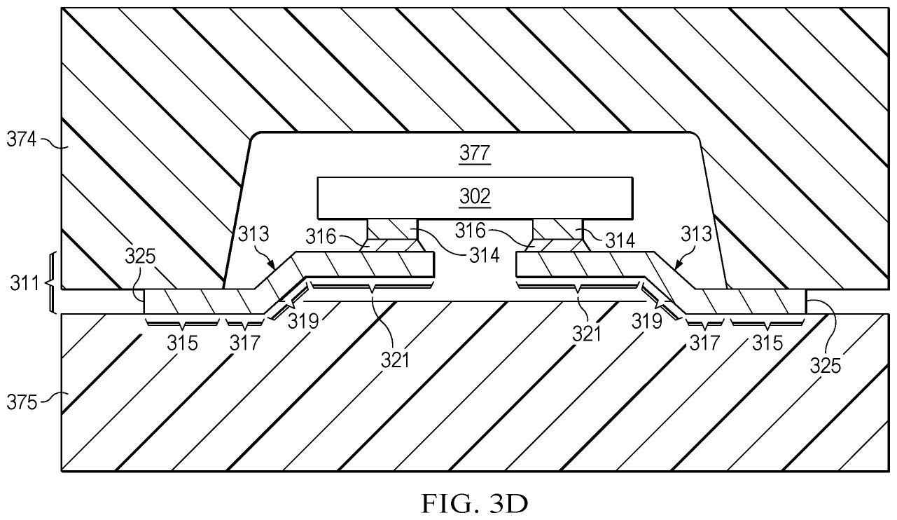

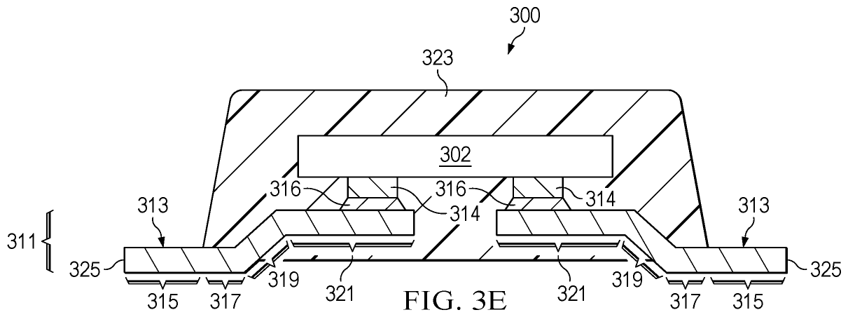

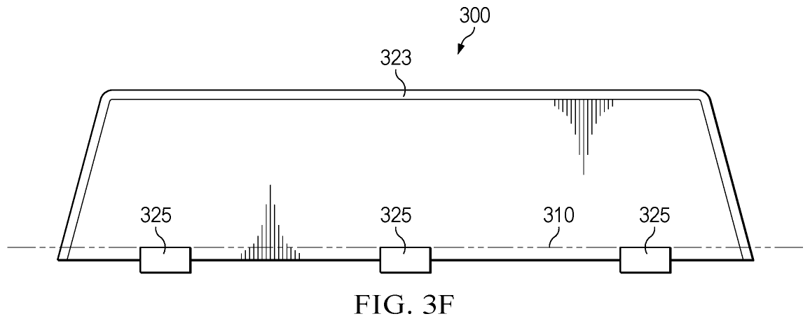

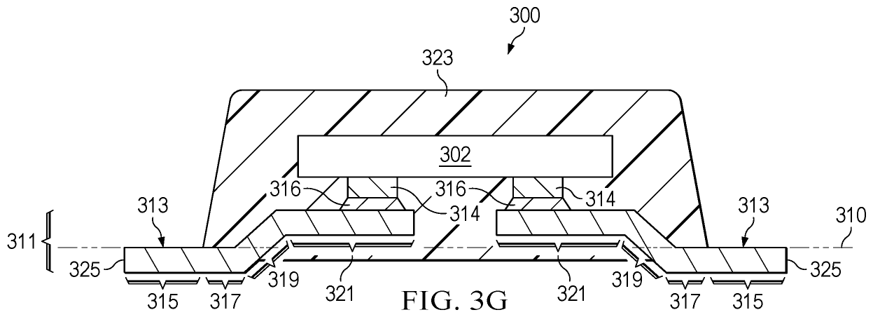

FIGS. 3A-3E illustrate in a series of steps a method for forming flip chip packaged electronic devices using solder bumps on post connects and an upset leadframe. In FIG. 3A, leadframe 311 has upset leads 313. The upset leads 313 have external portions 315 (portions that will be external to a package body formed in a later step) as indicated by the dashed lines 306. The external portions 315 have board side surfaces that will form terminals of a semiconductor device package in a later step. The upset leads 313 have an internal portion 317 that extends from the external portion 315 and which will be covered by the mold compound of the package body (formed in a later step) as indicated by the dashed line 306. The upset leads 313 have an angled portion 319 that begins at an interior end of the internal portions 317 and extends to an elevated portion 321. An angle 320 is formed between the internal portion 317 and the angled portion 319. In an example the angle 320 is about 120 degrees, an obtuse angle. Other angles can be used. The internal portion 317 and the external portion 315 lie in a first plane 360 (horizontal as the elements are shown in FIG. 3A), while the elevated portions 321 lie in a second plane 362 (also horizontal as the elements are oriented in FIG. 3A) that is parallel to the first plane, and the elevated portion 321 of the leads 313 is above the first plane 360 (as the elements are oriented in FIG. 3A). The elevated portions 321 have a device side surface 322 where post connects from a semiconductor die will be mounted (see FIG. 3C), in a later step. The upset leadframe 311 provides leads 313 that form terminals with a board side surface 312 for surface mounting the semiconductor device package, while elevating the semiconductor die above the board side surface so that the semiconductor die is in a center portion of the package body and is surrounded by mold compound in the finished device, as shown below (see FIG. 3C, for example).

In FIG. 3B, a semiconductor die 302, which can be similar to die 102 in FIG. 1B, is shown positioned for a flip chip assembly to the leadframe 311. The semiconductor die 302 has post connects 314 and solder bumps 316 extending from bond pads (not shown for simplicity of illustration) on the semiconductor die 302. The semiconductor die 302 is positioned in correspondence with the elevated portions 321 of the leads 313 of leadframe 311. The solder bumps 316 will be used to make solder connections between the semiconductor die 302 and the leads 313 of the leadframe 311 (see 316 in FIG. 3C as described below). The remaining portions of the leads 313, the external portions 315, the internal portions 317, angled portions 319 and angle 320 are shown as in FIG. 3A. The dashed lines 306 indicate where the package body will intersect leads 313.

FIG. 3C illustrates the semiconductor die 302 of FIG. 3B after a solder reflow process mounts semiconductor die 302 to the leadframe 311. Solder bumps 316 form solder joints on the elevated portions 321 of leads 313. Using a thermal reflow process, the solder bumps 316 are melted and then allowed to reflow and harden to form solder joints. The semiconductor die 302 is then physically mounted to and electrically coupled to the leads 313 by the solder bumps 316. The remaining portions of the lead 313, including the external portions 315, the internal portions 317, the angled portions 319 and angle 320 are again shown as in FIGS. 3A-3B. Dashed line 306 is again shown indicating where the package body will intersect leads 313 between the external portions 315 and the internal portions 317 of the leads 313.

In FIG. 3D, the assembled semiconductor die 302 and the leadframe 311 are shown positioned in a mold tool for a molding operation. A top mold chase 374 covers the semiconductor die 302 which is positioned in a cavity 377 in the top mold chase. A bottom mold chase 375 is clamped to the leads 313 and forms the bottom surface of the cavity 377. The mold tool can have multiple cavities 377 for mounting multiple leadframe and die assemblies to perform molding in parallel for several devices at the same time, increasing throughput.

In a transfer molding operation, a mold compound that may be a solid puck or a powder at room temperature is heated to a liquid or molten state. The liquid mold compound is forced into the mold cavity 377 using a mechanical ram to force the liquid mold compound into runners to fill the mold cavity 377. The mold compound can be a thermoset epoxy resin, an epoxy, a resin, or a plastic. The mold compound can include thermally conductive filler particles to enhance thermal performance. After the molding process, the mold compound cures to form a package body around the semiconductor die 302.

FIG. 3E illustrates in a cross sectional view a semiconductor device package 300 formed by the molding operation of FIG. 3D. Mold compound 323 is shown covering the semiconductor die 302 and parts of the leadframe 311 and portions of leads 313. The leads 313 each have an external portion 315 that is outside of the mold compound 323, a board side surface of the external portion 315 of the leads 313 forms terminals 325. The internal portions 317 of the leads 313 are covered on an upper surface by mold compound 323. The angled portion 319 of the leads 313 extends from the internal portion and form the upset shape of the leadframe 311, and the elevated portion 321 of the leads 313 supports the semiconductor die 302. By using an upset shaped leadframe 311, the semiconductor device package 300 provides terminals 325 on a board side surface for surface mounting, while the elevated portion 321 of the leads 313 places the semiconductor die 302 in a central portion of the semiconductor die package 300, the mold compound 323 surrounding the semiconductor die 302, the post connects 314, the solder joints 316 and portions of the leads 313. The semiconductor device package 300 can be a hermetic package to protect the semiconductor die from moisture or water intrusion.

FIG. 3F illustrates in a side view the semiconductor device package 300 of FIG. 3D. Terminals 325 are shown exposed from the mold compound 323. In FIG. 3F, a stress plane 310 is shown as dashed line, the stress plane 310 indicates a plane where delamination defects have been observed in packaged devices. As the elements are oriented in FIG. 3F, the stress plane 310 is a horizontal plane extending across the upper surface of the leads 313.

FIG. 3G illustrates, in a cross sectional view, the semiconductor device package 300 showing the stress plane 310. The stress plane 310 is shown aligned with the upper surface of the internal portions 317 of the leads 313, at the mold compound to lead interface. The upper surface of the internal portions 317 of the leads 313 can be pulled away from the mold compound 323 when delamination or cracking occurs. These delamination defects can cause devices to be scrapped in testing or at manufacture, or can cause failures in use in the field.

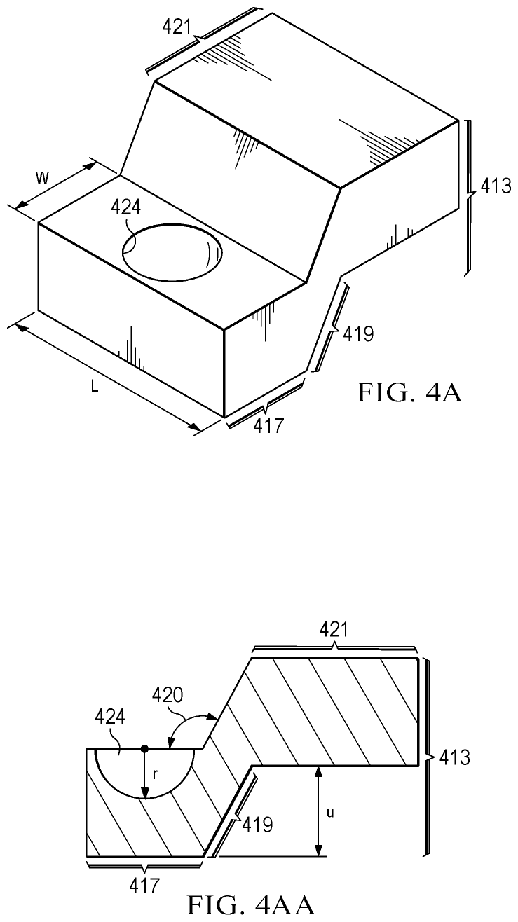

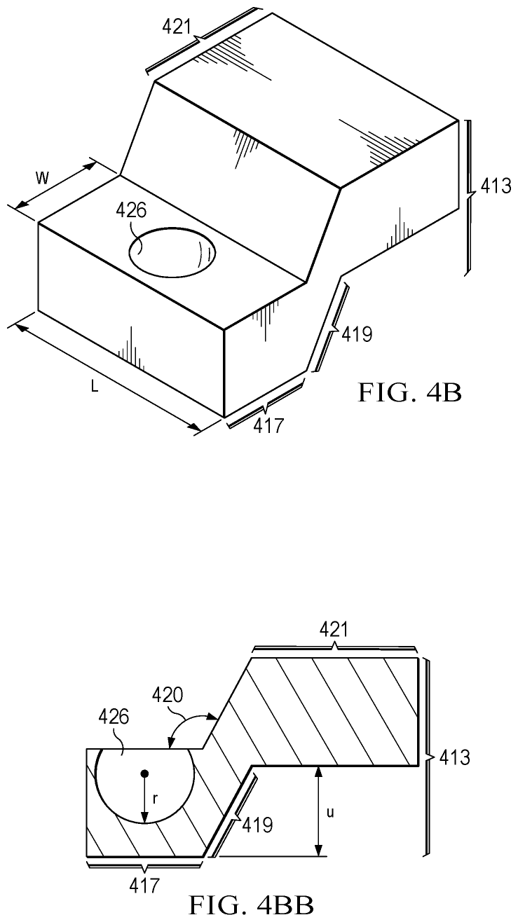

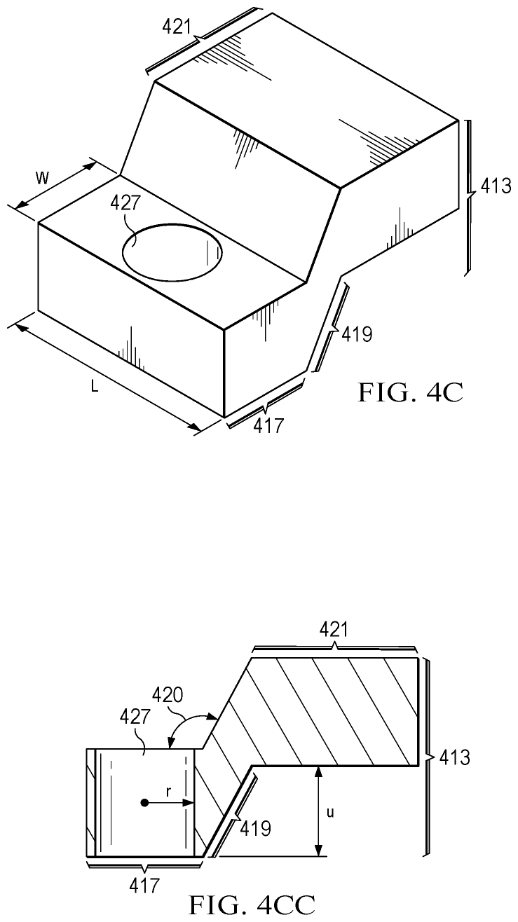

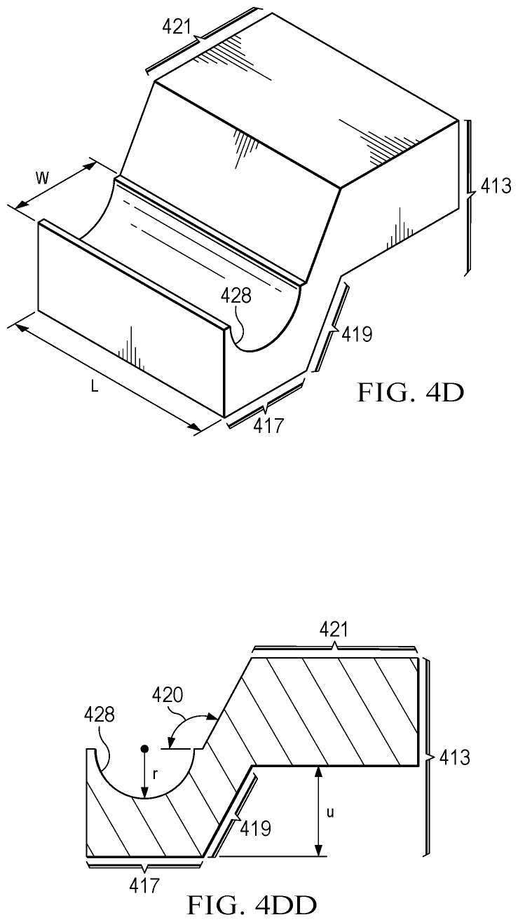

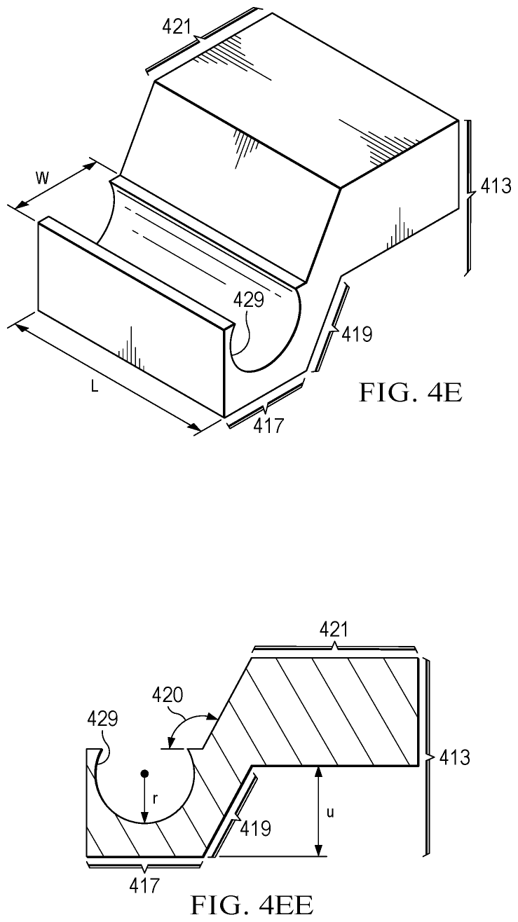

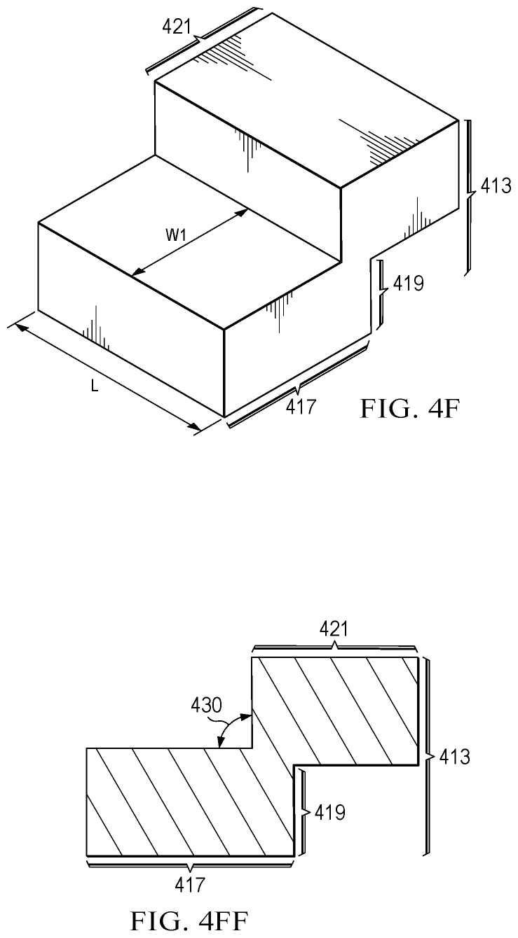

FIGS. 4A-4G and 4AA-4GG illustrate, in projection views, and in corresponding cross sectional views, respectively, portions of leads for use in example arrangements. In the arrangements, the force needed to cause a mold compound to pull away from the leads is increased by use of mold lock features that increase the surface area of the internal portion of the leads at the mold compound to lead interface. In some example arrangements, as is further described below, the surface area is increased by forming a mold lock feature as an indenture into the internal portion of the leads. In alternative arrangements, the surface area of the internal portions of the leads can be increased by changing the angle used in the upset lead arrangements to increase the area of the internal portion of the leads.

The use of the mold lock features of the arrangements increases the force needed to separate the mold compound from the leads. The force F needed to induce mold compound delamination or cracking is given by:

$$F = sA , \qquad ( Equation 1 )$$

where s is a tensile stress constant that is an intrinsic property of the materials that does not vary with area, and A is the surface area of the lead in contact with the mold compound.

In the illustrated arrangements, an upset leadframe is shown being used to form a semiconductor device package. The leads of the upset leadframe have external portions that are outside a package body formed by mold compound in a molding process. The external portions of the leads lie in a plane and are aligned to each other, and have board side surfaces that form surface mount terminals for the semiconductor device package. The leads have internal portions that extend from the external portions into the package body formed by the molding compound, the internal portions lie in the same plane as the external portions. The internal portions have an upper surface that faces away from a board side surface. The internal portions extend to an angled portion of the leads. The angled portions extend into the mold compound from the internal portion in a direction angled away from the board side surface to an elevated portion of the leads. The elevated portions of the leads have a device side surface facing away from the board side surface of the external portions and are aligned to each other and lie in a second plane that is parallel to the first plane. At least one semiconductor die is flip chip mounted to the device side surface of the elevated portions of the leads using solder bumps on conductive post connects.

In the arrangements, the force needed to separate the mold compound from the leads in increased by increasing the surface area of the upper surface of the internal portion of the leads. The arrangements increase the surface area by forming mold lock features into the upper surface of the internal portion of the leads. The mold lock features can be formed as indentures into the internal portion of the leads by stamping or etching processes during formation of the leadframe. In alternative arrangements, the surface area of the internal portion of the leads in increased by changing the angle of the angled portion of the leads to use a normal angle for the angled portion, or by using a reverse or acute angle for the angled portion, allowing an increase of the surface area of the internal portion while not changing the remaining portions of the leads. The increased surface area of the internal portion of the leads increases the force needed to remove the mold compound from the leadframe along the stress plane at the interface between the upper surface of the leads and the mold compound. Use of the arrangements reduces or eliminates delamination and mold cracking defects in semiconductor device packages formed without the arrangements.

In FIGS. 4A-4AA through FIGS. 4G-4GG, it is noted that the leads 413 illustrated are shown in part to illustrate the features, an external portion of the leads extending from the internal portion is not illustrated, and the elevated portion of the leads 421 is only partially illustrated, for simplicity of illustration.

FIGS. 4A-4AA are a projection view and a cross sectional view, respectively, that illustrate an example arrangement with a dip 424 formed as an indenture into the internal portion 417 of a lead 413. In FIG. 4A, a portion of lead 413, extending from the mold compound surface into the packaged device, is shown with internal portion 417, an angled portion 419 that extends from the internal portion into the package, and an elevated portion 421, corresponding to similar elements of lead 313 in FIG. 3E for example. (The external portion of the lead 413 is not shown, for simplicity of illustration.)

In FIG. 4AA, the lead 413 is shown in cross section with an angle 420 shown between the upper surface of the internal portion 417 and the angled portion 419. In an example the angle 420 is 120 degrees, however other angles can be used to form the leads 413. The dip 424 is a hemispherical shape with a radius “r” extending into the internal portion 417 of the lead 413, which increases the surface area (compared to a lead formed without the mold lock feature of the arrangements) and thus increases the force needed to cause delamination or cracking of the mold compound, which will extend into the dip 424.

FIGS. 4B-4BB are a projection view and a cross sectional view, respectively, that illustrate an alternative example arrangement. In FIGS. 4B-4BB, a mold lock feature with a groove 426 is formed as an indenture into the internal portion of a lead 413. In FIG. 4B, the mold lock feature of groove 426 is shown in a projection view illustrating a portion of a lead 413. Groove 426 is formed in the upper surface of the internal portion 417 of lead 413. The groove 426 is shown in FIG. 4BB in a cross sectional view, and has a shape of a partial sphere with a radius “r” that is open at the top. The groove is formed to a depth greater than the radius r, so that the groove has an open sphere shape. During molding, the groove 426 is open to expose the internal surface of the groove 426 to the mold compound, increasing the surface area at the mold compound to lead interface of the internal portion 417 of the lead 413. The lead 413 has an angled portion 419 that extends to the elevated portion 421 at an angle 420 in FIG. 4BB that can be the same angle as shown in FIG. 4AA, for example, about 120 degrees, or another angle.

FIGS. 4C-4CC are a projection view and a cross sectional view, respectively, that illustrate another alternative example arrangement with a through hole 427 formed through the internal portion of a lead 413. Through hole 427 can be formed by an etch process when the leadframe and the leads are formed. In FIG. 4B, a mold lock feature of through hole 427 is shown in a projection view illustrating a portion of a lead 413. The through hole 427 is formed extending from the upper surface of the internal portion 417 through the lead 413. The through hole 427 is shown in FIG. 4CC in a cross sectional view, and has a shape of a cylinder with a radius “r” that is open at the ends to expose the internal surface of the through hole 427 to the mold compound, increasing the surface area. The lead 413 has an angled portion 419 that extends to the elevated portion 421 at an angle 420 in FIG. 4CC that can be the same angle as shown in FIG. 4AA, for example, about 120 degrees, or another angle.

FIGS. 4D-4DD are a projection view and a cross sectional view, respectively, that illustrate an additional example arrangement. In FIGS. 4D-4DD, a dip canal 428 is formed as an indenture into the internal portion 417 of lead 413 using a similar shape as the dip in FIGS. 4A-4AA, now formed with a length “L” across the width “W” of the internal portion 417 of lead 413. Dip canal 428 can be formed by an etch process or by stamping when the leadframe is formed. In FIG. 4D, the mold lock feature, dip canal 428, is shown in a projection view illustrating a portion of a lead 413. The dip canal 428 is formed extending across the lead 413 with length “L” and indented into the lead 413 from the upper surface of the internal portion 417 through the lead 413. The dip canal 428 is shown in FIG. 4DD in a cross sectional view, and has a shape of a hemisphere with a radius “r” that is open at the top and the ends to expose the internal surface of the dip canal 428 to the mold compound, increasing the surface area. The lead 413 has an angled portion 419 that extends to the elevated portion 421 at an angle 420 in FIG. 4DD that can be, as an example, about 120 degrees, or another angle.

FIGS. 4E-4EE are a projection view and a cross sectional view, respectively, that illustrate an additional example arrangement. In FIGS. 4E-4EE, a groove canal 429 is formed across the internal portion 417 of a lead 413. The groove shaped 429 is similar to the groove in FIGS. 4B-4BB. The groove canal 429 can be formed by an etch process or by stamping when the leadframe is formed. In FIG. 4E, the mold lock feature, groove canal 429, is shown in a projection view illustrating a portion of a lead 413. The groove canal 429 is formed extending across the lead 413 with length “L” and is formed into the lead 413 from the upper surface of the internal portion 417. The groove canal 429 is shown in FIG. 4EE in a cross sectional view, and in the cross section, has a shape of a partial sphere with a radius “r” that is open at the ends and at the top to expose the internal surface of the groove canal to the mold compound, increasing the surface area. The groove canal is formed at a depth into the lead greater than the radius r so that in cross section, the groove canal appears as a spherical shape with an open top. The lead 413 has an angled portion 419 that extends to the elevated portion 421 at an angle 420 in FIG. 4EE that can be, as an example, about 120 degrees, or another angle.

FIGS. 4F-4FF illustrate in a projection view, and a cross sectional view, respectively, another alternative arrangement. In FIG. 4F, a portion of the lead 413 is shown with internal portion 417 having an extended width (when compared to the arrangements of FIGS. 4A-4E, for example) W1. The surface area of the internal portion 417 of the lead 413 is increased in this arrangement by using a normal angle 430 between the upper surface of the internal portion 417 and the angled portion 419, instead of the obtuse angles used in the other arrangements, and instead of the angle used in an upset lead formed without the use of the arrangements. Using the normal angle 430 with a vertical angled portion 419 (as the elements are oriented in the figures) allows the width W1 of the internal portion 417 to be increased (compared to an upset lead design with an obtuse angle, for example) without changing the overall length or width of the lead 413, or the position or size of elevated portion 421, which is used for flip chip mounting of a semiconductor die. Because the surface area of the internal portion 417 is increased, the delamination and cracking problems observed in prior approach upset leads are reduced or eliminated. FIG. 4FF illustrates the normal angle 430 between the internal portion 417 and the angled portion 419 in lead 413 in a cross sectional view.

FIGS. 4G-4GG illustrate in a projection view, and a cross sectional view, respectively, an additional alternative arrangement. In FIG. 4G, a portion of the lead 413 is shown with internal portion 417 having an extended width W2 (extended when compared to the arrangements of FIGS. 4A-4E, for example). As shown in FIG. 4GG, the surface area of the internal portion is increased in this arrangement by using an acute angle 434 between the upper surface of the internal portion 417 and the angled portion 419. In the illustrated example an angle 434 of 60 degrees is shown. Other acute angles can be used. By using an acute angle 434 with the angled portion 419, the arrangement of FIGS. 4G-4GG allows the width W2 of the internal portion 417 to be further increased (compared to the normal angle of FIGS. 4F-4FF, for example), in FIGS. 4G-4GG the angled portion 419 has a “reverse” slope (directed back over the internal portion 417) and the width W2 can be increased without changing size of elevated portion 421, which is used for flip chip mounting of a semiconductor die. Because the surface area of the internal portion 417 is again increased, the delamination and cracking problems observed in prior approach upset leads are reduced or eliminated. FIG. 4GG illustrates the acute angle 434 between the internal portion 417 and the angled portion 419 in lead 413 in a cross sectional view.

Table 1 compares formulas for the surface area of the interior portion of an upset lead design formed without the use of any of the arrangements to the surface area for each of the example arrangements illustrated in FIGS. 4A-4AA through 4G-4GG. The lead formed without the arrangements, shown in the row labeled “Original, not using the arrangements”, has a surface area that is the product of the lead length L and the lead width W. Each of the formulas shown in the remaining rows has an increased surface area over the “Original” lead and the table shows each arrangement on a separate row. The row in Table 1 labeled “Dip (indented into the surface)” corresponds to FIGS. 4A-4AA, while the row labeled “Groove (indented into the surface)” corresponds to FIGS. 4B-4BB. Similarly, the row labeled “Through Hole (extending into surface through lead)” corresponds to the arrangement shown in FIGS. 4C-4CC. The rows labeled “Dip Canal (extending across length of lead)” and “Groove Canal (extending across length of lead)” correspond to the arrangements shown in FIGS. 4D-4DD and 4E-4EE, respectively. The rows labeled “90 Degree upset lead” and “60 Degree upset lead” correspond to the arrangements shown in FIGS. 4F-4FF and 4G-4GG, respectively.

TABLE 1

| Lead shape | Surface Area of Internal Portion of Lead |
|---|---|
| Original (not using the arrangements) | A_{O} = LW |
| Dip (indented into surface) | ${A}_{D} = LW + π {r}^{2} ; r = \frac{W}{4}$ |
| Groove (indented into surface) | ${A}_{G} = L W + \frac{9}{4} π {r}^{2} ; r = \frac{W}{4}$ |
| Through Hole (extending into surface through lead) | ${A}_{TH} = 2 LW - 2 π {r}^{2} ; r = \frac{W}{4}$ |
| Dip Canal (extending across length of lead) | ${A}_{DC} = LW + 1.1416 rW ; r = \frac{W}{4}$ |
| Groove Canal (extending across length of lead) | ${A}_{GC} = LW + 3.298 rW ; r = \frac{W}{4}$ |
| 90 Degree upset lead | ${A}_{90} = ( L + u tan 30 ° ) W ; u = upset height$ |
| 60 Degree upset lead | ${A}_{60} = L W + 2 u tan 30 {°}^{)} W ; u = upset height$ |

The formulas shown in Table 1 show the increased surface area obtained for the example arrangements. In Table 2, an example implementation with a leadframe upset lead having a lead length “L” of 0.142 millimeters, a lead width “W” of 0.23 millimeters, and an upset height “u” of 0.085 millimeters, is evaluated for each of the arrangements. The rows of Table 2 have the same labels as in Table 1.

TABLE 2

| Lead Design | Area in millimeters squared (mm²) |
|---|---|
| Original (not using | Aₒ = 0.03266 |
| the arrangements) | |
| Dip (indented into surface) | A_{D} = 0.04305 |
| Groove (indented into surface) | A_{G} = 0.05603 |
| Through Hole (extending | A_{TH} = 0.04454 |
| into surface through lead) | |
| Dip Canal (extending across | A_{DC} = 0.05138 |
| length of lead) | |
| Groove Canal (extending | A_{GC} = 0.07628 |
| across length of lead) | |
| 90 Degree upset lead | A₉₀ = 0.04395 |
| 60 Degree upset lead | A₆₀ = 0.05523 |

As shown by comparing the rows in Table 2 the row labeled “Groove Canal (extending across length of lead)” has the greatest surface area obtained for the arrangement of FIGS. 4E-4EE, the groove canal 429 extending across the width of the lead 413. The row labeled “60 Degree upset lead”, corresponding to the arrangement of FIGS. 4G-4GG, also has good performance, as does the groove of FIGS. 4B-4BB, the surface area is shown in the row labeled “Groove (indented into surface).”

Table 3 illustrates the increase in the surface area A of the internal portion of the leads, and the corresponding increase in the force F needed to separate the mold compound from the leads at the mold compound to lead interface, by comparing the surface area obtained using the various arrangements to the lead formed without use of the arrangements. The row labeled “Original (not using the arrangements)”, which has an area labeled Aₒ, and a force Fₒ, is for an upset lead formed without the arrangements. In Table 3, for each row (the rows being labeled the same as in Table 1 and Table 2), the surface area is shown as a ratio to Aₒ, and the force is shown as a product with Fₒ. As shown in Table 3, the arrangement of FIGS. 4E-4EE, the groove canal, has the largest increase, a force increase of 2.3356 Fₒ. Thus use of the groove canal arrangement in the internal portion of the upset lead results in a force over twice as great as the force for a lead formed without use of the arrangements, increasing the force needed to remove the mold compound from the leads.

Use of the arrangements provides an upset leadframe and a semiconductor device package formed using the upset leadframe with reduced or eliminated delamination defects and reduced mold compound cracking. The internal portion of the leads has increased surface area formed by use of mold lock features. The mold lock features of the arrangements includes dips, grooves, and through holes formed into an upper surface of an internal portion of the leads, and dip canals and groove canals formed into the upper surface of the internal portion of the leads. Alternative mold lock features of the arrangements include use of a normal (90 degree) angle between the internal portion of the leads and an angled portion, and the use of an acute (less than 90 degree) angle between the internal portion of the leads and the angled portion to increase the surface area of the upper surface of the internal portion.

TABLE 3

| Lead Design | Area Ratio | Force Ratio |
|---|---|---|
| Original (not using the | Aₒ/Aₒ = 1 | Fₒ = Fₒ |
| arrangements) | | |
| Dip (indented into | A_{D}/Aₒ = 1.3181 | F_{D} = 1.3181 Fₒ |
| surface) | | |
| Groove (indented into | A_{G}/Aₒ = 1.7156 | F_{G} = 1.7156 Fₒ |
| surface) | | |
| Through Hole (extending | A_{TH}/Aₒ = 1.3637 | F_{TH} = 1.3637 Fₒ |
| into surface through lead) | | |
| Dip Canal (extending | A_{DC}/Aₒ = 1.5732 | F_{DC} =1.5732 Fₒ |
| across length of lead) | | |
| Groove Canal (extending | A_{GC}/Aₒ = 2.3356 | F_{GC} = 2.3356 Fₒ |
| across length of lead) | | |
| 90 Degree upset lead | A₉₀/Aₒ = 1.3457 | F₉₀ = 1.3457 Fₒ |
| 60 Degree upset lead | A₆₀/Aₒ = 1.6911 | F₆₀ = 1.6911 Fₒ |

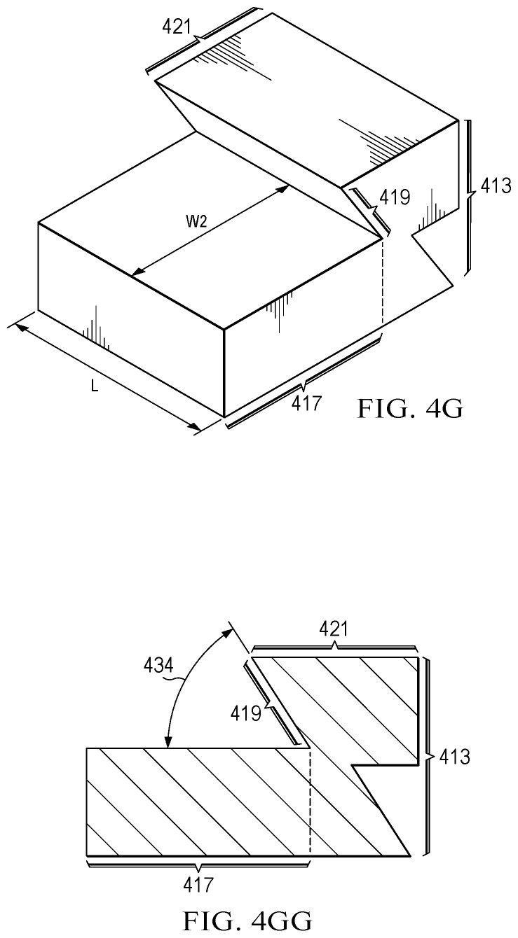

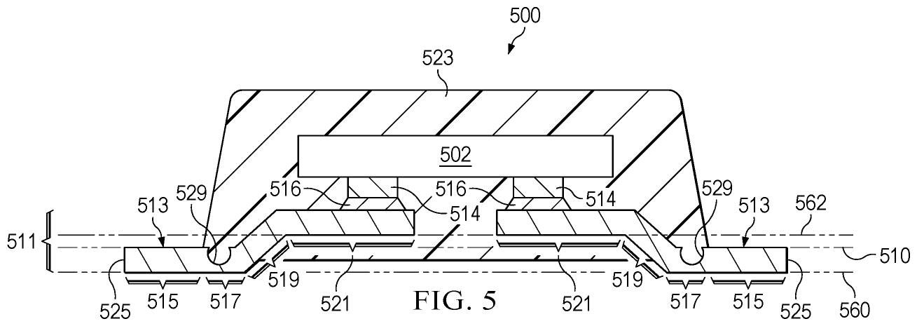

FIG. 5 illustrates, in a cross sectional view, a semiconductor device package 500 formed using the groove canal arrangement shown in FIGS. 4E-4EE. The semiconductor device package 500 includes a lead frame 511 which an upset lead leadframe similar to the leadframe 311 in FIG. 3. The leads 513 are shown with a semiconductor die 502 flip chip mounted to the elevated portions 521 of the leads 513. The semiconductor die 502 includes post connects 514 extending from the semiconductor die 502, and solder bumps 516 are used to form solder joints to the leads 513 in the elevated portions 521. Each lead 513 has terminals 525 formed on a board side surface of the leads of leadframe 511. The leads 513 have external portions exposed from the mold compound 523 with board side surfaces forming terminals 525, and have internal portions 517 with mold lock features extending into the upper surface of the internal portions 517 of the leads 513; in the illustrated example a groove canal 529 is shown as the mold lock feature. The external portions 515 and the internal portions 517 lie in a first plane 560 (horizontal plane as the elements are oriented in FIG. 5).

The angled portions 519 extend from the internal portions 517 at an angle with respect to the internal portions and extend to the elevated portions 521, which lie in a second plane 562 that is parallel to the first plane 560 and spaced from it. The package 500 is shown with a stress plane 510 shown at the interface between the upper surface of the internal portions 517 of the leads 513 and the mold compound 523. The use of the mold lock features of groove canals 529 of the arrangements adds surface area to the internal portions 517 of the leads 513 and increases the force needed to separate the mold compound 523 from the leads 513 by over twice the force needed for semiconductor device packages formed without use of the arrangements, as shown in Tables 1, 2 and 3 and discussed above. The alternative mold lock features of the dip of FIGS. 4A-4AA, the groove of FIGS. 4B-4BB, the through hole of FIGS. 4C-4CC, the dip canal of FIGS. 4D-4DD, and the normal angle or the acute angle of FIGS. 4E-4EE and FIGS. 4F-4FF can be used as described above. In addition, additional arrangements can be formed by combining one of the indenture features (dip, groove, through hole, dip canal, groove canal) with the normal angle in the angled portion, or with the acute angle in the angled portion, to form additional semiconductor device packages with mold lock features for increased lead surface area.

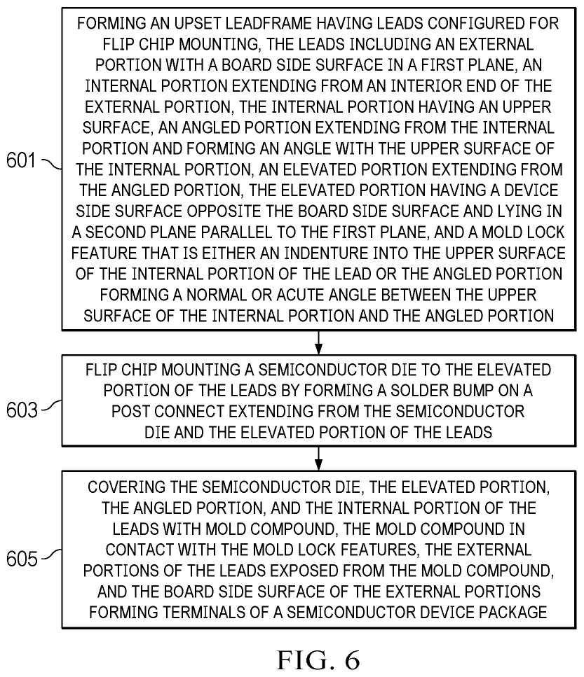

FIG. 6 illustrates, in a flow diagram, selected steps of the methods described above for forming the arrangements. In FIG. 6, the method begins at step 601 by forming an upset leadframe having leads configured for flip chip mounting. The leads include (see 413 in FIGS. 4A-4AA for example) an external portion with a board side surface in a first plane, an internal portion extending from an interior end of the external portion, the internal portion having an upper surface, an angled portion extending from the internal portion and forming an angle with the upper surface of the internal portion, an elevated portion extending from the angled portion, the elevated portion having a device side surface opposite the board side surface and lying in a second plane parallel to the first plane, and a mold lock feature that is either an indenture into the upper surface of the internal portion of the lead or the angled portion forming a normal or acute angle between the upper surface of the internal portion and the angled portion by forming a passivation layer over bond pads of a semiconductor device. (See FIGS. 4A-4F and FIGS. 4AA-4FF showing leads 413, with internal portions 417, angled portions 419, elevated portions 421, and mold lock features including indentures 424, 426, 427, 428, 429, and angles 430, 434).

At step 603 in FIG. 6, the method continues by flip chip mounting a semiconductor die to the elevated portion of the leads by forming a solder joint between a solder bump on a post connect extending from the semiconductor die and the elevated portion of the leads (see, for example, semiconductor die 502 in FIG. 5 with post connects 514 and solder bumps 516 on elevated portions 521 of the leads 513 of leadframe 511).

At step 605 in FIG. 6, the method continues by covering the semiconductor die, the elevated portion, the angled portion, and the internal portion of the leads with mold compound, the mold compound in contact with the mold lock features, the external portions of the leads exposed from the mold compound, and the board side surface of the external portions forming terminals of a semiconductor device package. (See, for example, FIG. 5, mold compound 523, with leadframe 511 having external portions 515 and terminals 525).

Use of the arrangements provides flip chip semiconductor device packages with improved adhesion between mold compound forming a package body and the leads of an upset leadframe. Mold lock features formed in the internal portions of the leads of the leadframe eliminate or reduce delamination and cracking defects in the packaged devices. The mold lock features can include indentures into the internal portion of the leads or normal or acute angles between the internal portion of the leads and an angled portion of the leads, the mold lock features increase the surface area of the leads where mold compound contacts the leads, and thereby reduce the delamination and cracking defects. The mold lock features can be formed by stamping or etching processes when the leadframe is manufactured.

Modifications are possible in the described arrangements, and other alternative arrangements are possible within the scope of the claims.

What is claimed is:

1. A method, comprising:
forming an upset leadframe having leads configured for flip chip mounting a semiconductor die, the leads comprising:
an external portion with a board side surface in a first plane;
an internal portion extending from an interior end of the external portion, the internal portion having an upper surface opposite the board side surface, the internal portion lying in the first plane;
an angled portion extending from the internal portion opposite the external portion, the angled portion forming an angle with the upper surface and extending away from the internal portion;
an elevated portion extending from the angled portion, the elevated portion having a device side surface facing opposite the board side surface and lying in a second plane that is parallel to the first plane; and
a mold lock feature comprising either an indenture into the upper surface of the internal portion or the angle of the angled portion being either a normal angle or an acute angle formed between the upper surface of the internal portion and the angled portion;
flip chip mounting a semiconductor die to the elevated portion of the leads by forming a solder joint between a solder bump on a post connect extending from the semiconductor die and the elevated portion of the leads; and
covering the semiconductor die, the elevated portion, the angled portion, and the internal portion of the leads with mold compound, the mold compound in contact with the mold lock features, the external portions of the leads exposed from the mold compound, and wherein the board side surface of the external portions of the leads form terminals of a semiconductor device package.

2. The method of claim 1, wherein the mold lock feature comprises the indenture into the upper surface of the internal portion of the lead that is a dip into the internal portion, a groove into the internal portion, a through hole extending through the internal portion, a dip canal into the internal portion and extending across the internal portion, or a groove canal into the internal portion and extending across the internal portion.

3. The method of claim 1, wherein the semiconductor device package further comprises a small outline transistor (SOT) package.

4. The method of claim 1, wherein the mold lock feature comprises a groove canal into and extended across the internal portion of the leads.

5. The method of claim 1, wherein the mold lock feature comprises a dip canal into and extending across the internal portion of the leads.

6. The method of claim 1, wherein the mold lock feature comprises a through hole extending into and through the internal portion of the leads.

7. The method of claim 1, wherein the mold compound comprises a thermoset epoxy resin.

8. The method of claim 1, wherein the terminals are configured for surface mounting to a system board using solder.

9. The method of claim 1, wherein forming the mold lock features further comprises performing an etch process on the leads of the leadframe.

10. The method of claim 1, wherein forming the mold lock features further comprises performing a stamping process on the leads of the leadframe.

11. The method of claim 1, wherein forming the mold lock features further comprises forming the indenture into the upper surface of the internal portion and forming the angle of the angled portion to be a normal angle or an acute angle between the upper surface of the internal portion and the angled portion.

12. An apparatus, comprising:
a leadframe having upset leads configured for flip chip mounting a semiconductor die, the leads further comprising:
an external portion with a board side surface in a first plane;
an internal portion extending from an interior end of the external portion, the internal portion having an upper surface opposite the board side surface;
an angled portion extending from the internal portion opposite the external portion, the angled portion forming an angle with the upper surface of the internal portion and extending away from the internal portion;
an elevated portion extending from the angled portion, the elevated portion having a device side surface opposite the board side surface and lying in a second plane parallel to the first plane; and
a mold lock feature comprising an indenture into the upper surface of the internal portion or the angle of the angled portion being either a normal angle or an acute angle formed between the upper surface of the internal portion and the angled portion;
a semiconductor die flip chip mounted to the elevated portion of the leads by solder joints between a solder bump on a post connect extending from the semiconductor die and the elevated portion of the leads; and
mold compound covering the semiconductor die, the post connects, the elevated portion, the angled portion, and the internal portion of the leads of the leadframe, the mold compound in contact with the mold lock feature of the leads, the external portions of the leads exposed from the mold compound, and the board side surface of the external portions of the leads forming terminals of a semiconductor device package.

13. The apparatus of claim 12, wherein the mold lock features of the leads comprise the indenture into the upper surface of the internal portion comprising a dip into the upper surface of the internal portion, a groove into the upper surface of the internal portion, a dip canal extending across the internal portion of the lead, a groove canal extending across the internal portion of the lead, or a through hole extending into the upper surface of the internal portion of the lead and through the lead.

14. The apparatus of claim 12, wherein the mold lock features of the leads further comprise the angle of the angled portion of the lead being a normal angle or an acute angle with respect to the upper surface of the internal portion of the leads.

15. The apparatus of claim 12, wherein the semiconductor device package further comprises a small outline transistor (SOT) package.

16. The apparatus of claim 12, wherein the mold lock features of the leads further comprise the indenture into the upper surface of the internal portion that is a dip canal into the internal portion that extends across the internal portion.

17. The apparatus of claim 12, wherein the mold lock features of the leads further comprise the indenture into the upper surface of the internal portion that is a groove canal into the internal portion that extends across the internal portion.

18. The apparatus of claim 12, wherein the mold lock features of the leads further comprise the an indenture into the upper surface of the internal portion that is a dip into the internal portion, a groove into the internal portion, a through hole extending through the internal portion, a dip canal into and extending across the internal portion, a groove canal into and extending across the internal portion, and the angle formed between the upper surface of the internal portion and the angled portion of the leads being a normal angle or an acute angle.

19. The apparatus of claim 12, wherein the mold lock features of the leads further comprise an indenture into the upper surface of the internal portion that is a groove canal into and extending across the internal portion.

20. The apparatus of claim 12, wherein the semiconductor die comprises at least one field effect transistor (FET).
